(19) United States
(12) Patent Application Publication
(10) Pub. No.: US 2013/0141969 A1
(43) Pub. Date: Jun. 6, 2013

(54) SEMICONDUCTOR INTEGRATED CIRCUIT AND SEMICONDUCTOR MEMORY

(71) Applicant: Yoshihide NAKAJIMA, Yokohama-shi (JP)

(72) Inventor: Yoshihide NAKAJIMA, Yokohama-shi (JP)

(73) Assignee: Kabushiki Kaisha Toshiba, Tokyo (JP)

(21) Appl. No.: 13/400,781

(22) Filed: Feb. 21, 2012

(30) Foreign Application Priority Data
Dec. 2, 2011 (JP) 2011-264666

(51) Int. Cl. G11C 16/06; H03K 5/22

(52) U.S. Cl. 365/185.2; 327/72

(57) ABSTRACT

A semiconductor integrated circuit includes a first constant current output circuit that outputs a first constant current from a first constant current terminal to a first output terminal. The semiconductor integrated circuit includes an error current output circuit that outputs an error current from an error current terminal to the first output terminal.

### CROSS-REFERENCE TO RELATED APPLICATION

This application is based upon and claims the benefit of priority from the prior Japanese Patent Application No.2011-264666, filed on Dec. 2, 2011, the entire contents of which are incorporated herein by reference.

### BACKGROUND

1. Field

Embodiments described herein relate generally to a semiconductor integrated circuit and a semiconductor memory.

2. Background Art

For sense amplifiers in semiconductor memories such as flash memories, variations in constant current between memory cells in a memory cell array need to be suppressed. Thus, a constant current has to be adjusted with high precision.

To obtain a constant current with high precision in a conventional technique, variations in current are adjusted in each block by trimming. This technique, however, requires a minimum current step to increase a test time and precisely obtain a current. Moreover, adjustments on currents over a wide range may increase the size of a trimming circuit.

### BRIEF DESCRIPTION OF THE DRAWINGS

FIG. 1 is a diagram showing an example of the configuration of a semiconductor memory 1000 according to a first embodiment;

FIG. 2 is a diagram showing an example of a configuration including the semiconductor integrated circuit 100 and the sense amplifier 1005 according to the first embodiment;

FIG. 3 is a circuit diagram illustrating an example of the configuration of the error current output circuit C1 illustrated in FIG. 2;

FIG. 4 is a diagram showing an output current distribution of the constant current output circuit without the application of the first embodiment;

FIG. 5 is a diagram showing a current distribution when a constant current from a constant current output circuit is trimmed by a conventional trimming circuit;

FIG. 6 is a diagram showing an output current distribution of the semiconductor integrated circuit 100 according to the first embodiment;

FIG. 7 is a diagram showing an example of the configuration of a semiconductor integrated circuit 200 according to the second embodiment; and

FIG. 8 is a circuit diagram showing an example of the configuration of the monitor selecting circuit 4 illustrated in FIG. 7.

### DETAILED DESCRIPTION

A semiconductor integrated circuit according to an embodiment includes a first constant current output circuit that outputs a first constant current from a first constant current terminal to a first output terminal. The semiconductor integrated circuit includes an error current output circuit that outputs an error current from an error current terminal to the first output terminal.

The error current output circuit includes a current comparator circuit that compares a monitor current obtained by monitoring an output current from the first output terminal and a reference current, outputs a first comparison result current obtained by subtracting the monitor current from the reference current, and outputs a second comparison result current obtained by subtracting the reference current from the monitor current.

The error current output circuit includes a first amplifier circuit that amplifies the first comparison result current to output a first amplified current of a first polarity.

The error current output circuit includes a second amplifier circuit that amplifies the second comparison result current to output a second amplified current of a second polarity opposite to the first polarity.

In the case where the reference current is larger than the monitor current, the first amplified current is outputted as the error current from the error current terminal.

In the case where the reference current is smaller than the monitor current, the second amplified current is outputted as the error current from the error current terminal.

Embodiments will be described below with reference to the accompanying drawings. In the following embodiments, the present invention is applied to semiconductor memories (e.g., flash memories including a NAND flash memory and a NOR flash memory).

### First Embodiment

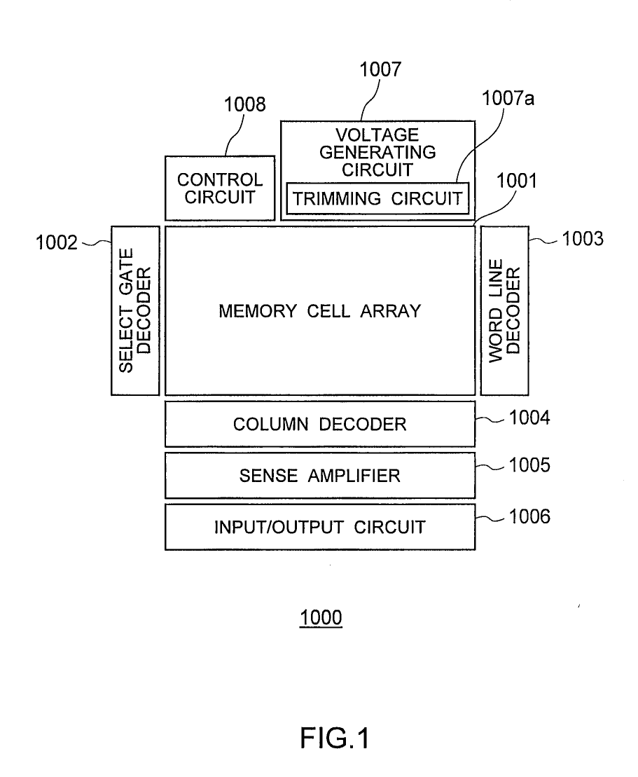

FIG. 1 illustrates an example of the configuration of a semiconductor memory 1000 according to a first embodiment.

As illustrated in FIG. 1, the semiconductor memory 1000 includes a memory cell array 1001, a select gate decoder 1002, a word line decoder 1003, a column decoder 1004, a sense amplifier 1005, an input/output circuit 1006, a voltage generating circuit 1007, and a control circuit 1008.

The memory cell array 1001 includes a plurality of bit lines, a plurality of word lines, a select gate line, and a source line. The memory cell array 1001 includes, for example, a plurality of blocks (not shown), each having memory cells arranged in matrix. The memory cells are EEPROM cells in which data is electrically rewritable.

The memory cell array 1001 is connected to a sense amplifier 1005 that controls the voltages of the bit lines, a word line decoder 1003 that controls the voltages of the word lines connected to the memory cells, and the select gate decoder 1002 that controls a select gate for selecting the blocks. When data is written, any one of the blocks is selected by the select gate decoder 1002 while the other blocks are not selected.

The sense amplifier 1005 reads data in the memory cells of the memory cell array 1001 through the bit lines, detects the states of the memory cells through the bit lines, and applies a writing control voltage to the memory cells through the bit lines to write data in the memory cells.

The sense amplifier 1005 is connected to the column decoder 1004 and the input/output circuit 1006. A sense amplifier circuit S/A in the sense amplifier 1005 is selected by the column decoder 1004. Memory cell data read by the sense amplifier circuit S/A is outputted to the outside through the input/output circuit 1006.

Moreover, written data inputted from the outside is stored through the input/output circuit 1006 into the memory cell array selected by the column decoder 1004.

The select gate decoder 1002 is connected to the memory cell array 1001. The select gate decoder 1002 selects a block of the memory cell array 1 in response to an address signal for selecting the block. Then, the word line decoder 1003 applies a voltage required for reading, writing, or deletion from the voltage generating circuit 1007 to the word lines of the selected block.

The control circuit 1008 controls the operations of the memory cell array 1001, the select gate decoder 1002, the word line decoder 1003, the column decoder 1004, the sense amplifier 1005, and the input/output circuit 1006.

The voltage generating circuit 1007 optionally raises a power supply voltage and supplies the voltage to the select gate decoder 1002, the word line decoder 1003, the column decoder 1004, the sense amplifier 1005, and the input/output circuit 1006.

The voltage generating circuit 1007 includes a trimming circuit 1007a containing a semiconductor integrated circuit 100 described below for automatically adjusting an output current.

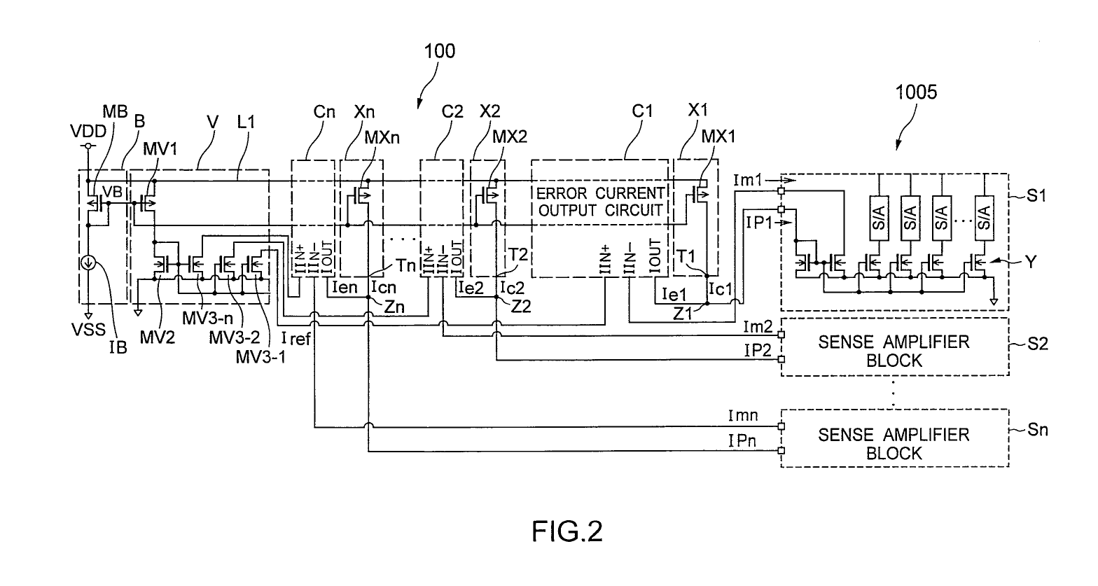

FIG. 2 illustrates an example of a configuration including the semiconductor integrated circuit 100 and the sense amplifier 1005 according to the first embodiment.

A plurality of (n) sense amplifier blocks S1 to Sn in FIG. 2 correspond to the sense amplifier 1005 in FIG. 1.

For example, as illustrated in FIG. 2, the sense amplifier block S1 includes a plurality of sense amplifier circuits S/A and current mirror circuits Y.

As described above, the sense amplifier circuits S/A are connected to the memory cell array 1001.

The current mirror circuits Y supply a current obtained by current-mirroring an output current IP1 outputted from the semiconductor integrated circuit 100, to the sense amplifier circuits S/A. Furthermore, the current mirror circuits Y output a monitor current Im1 that is obtained by current-mirroring the output current IP1.

The other sense amplifier blocks S2 to Sn are identical in configuration to the sense amplifier block S1.

The semiconductor integrated circuit 100 in FIG. 2 is provided in the trimming circuit 1007a of FIG. 1.

The semiconductor integrated circuit 100 supplies the output current IP1 to IPn to the sense amplifier blocks S1 to Sn through first to n-th output terminals Z1 to Zn.

As described above, the sense amplifier blocks S1 to Sn output the monitor current Im1 to Imn which are obtained by current-mirroring the output currents IP1 to IPn through the current mirror circuits Y. Furthermore, the semiconductor integrated circuit 100 compares the monitor currents Im1 to Imn and a reference current Iref and then adjusts the output currents IP1 to IPn to a predetermined value according to the comparison result.

As illustrated in FIG. 2, the semiconductor integrated circuit 100 includes, for example, first, second . . . and n-th constant current output circuits X1, X2, . . . and Xn, n error current output circuits C1, C2, . . . and Cn, a bias voltage generating circuit B, and a reference current generating circuit V.

The first constant current output circuit X1 outputs a first constant current IC1 from a first constant current terminal T1 to the first output terminal Z1.

As illustrated in FIG. 2, the first constant current output circuit X1 includes, for example, a constant current MOS transistor (pMOS transistor) MX1 having one end (source) connected to a first potential line L1, a gate fed with a bias voltage VB, and the other end (drain) from which the first constant current IC1 is outputted.

The second constant current output circuit X2 outputs a second constant current IC2 from a second constant current terminal T2 to the second output terminal Z2.

As illustrated in FIG. 2, the second constant current output circuit X2 includes, for example, a constant current MOS transistor (pMOS transistor) MX2 having one end (source) connected to the first potential line L1, a gate fed with the bias voltage VB, and the other end (drain) from which the second constant current IC2 is outputted.

Likewise, the n-th constant current output circuit Xn outputs an n-th constant current ICn from an n-th constant current terminal Tn to the n-th output terminal Zn.

As illustrated in FIG. 2, the n-th constant current output circuit Xn includes, for example, a constant current MOS transistor (pMOS transistor) MXn having one end (source) connected to the first potential line L1, a gate fed with the bias voltage VB, and the other end (drain) from which the n-th constant current ICn is outputted.

As described above, the second to n-th constant current output circuits X2 to Xn are identical in configuration to the first constant current output circuit X1.

The error current output circuit C1 outputs an error current Ie1 from an error current terminal IOUT to the first output terminal Z1.

The error current output circuit C2 outputs an error current Ie2 from an error current terminal IOUT to the second output terminal Z2.

Likewise, the error current output circuit Cn outputs an error current Ten from an error current terminal IOUT to the n-th output terminal Zn.

The bias voltage generating circuit B generates the bias voltage VB.

As illustrated in FIG. 2, the bias voltage generating circuit B includes, for example, a first bias MOS transistor (pMOS transistor) MB of a second conductivity type and a bias current source IB.

The first bias MOS transistor MB has one end (source) connected to the first potential line L1 and the other end (drain) from which the bias voltage VB is outputted.

The bias current source IB is connected between the other end (drain) of the first bias MOS transistor MB and a second potential line L2 to output a current.

The reference current generating circuit V generates the reference current Iref.

As illustrated in FIG. 2, the reference current generating circuit includes, for example, a first reference MOS transistor MV1 of the second conductivity type, a second reference MOS transistor MV2 of the second conductivity type, and multiple (n) third reference MOS transistors MV3-1 to MV3-n.

The first reference MOS transistor MV1 has one end (source) connected to the first potential line L1 and a gate connected to the gate of the first bias MOS transistor MB.

The first reference MOS transistor MV1 is fed with a current obtained by current-mirroring a current passing through the bias MOS transistor MB (the output current of the bias current source IB).

The second reference MOS transistor MV2 is diode-connected between the other end (drain) of the first reference MOS transistor and the second potential line L2.

The third reference MOS transistors MV3-1 to MV3-n each have one end (drain) from which the reference current Iref is outputted, the other end (source) connected to the second potential line L2, and a gate connected to the gate of the second reference MOS transistor MV2.

The third reference MOS transistors MV3-1 to MV3-n are fed with a second amplified current Ix2 obtained by current-mirroring a current passing through the second reference MOS transistor MV2 (that is, a current obtained by current-mirroring the output current of the bias current source IB).

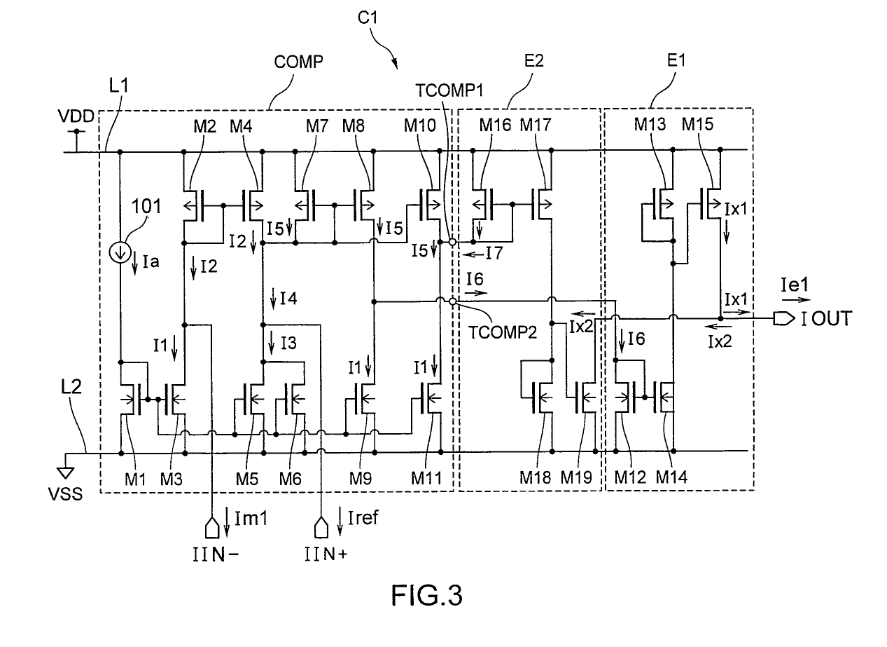

FIG. 3 is a circuit diagram illustrating an example of the configuration of the error current output circuit C1 illustrated in FIG. 2. The other error current output circuits C2 to Cn are identical in, for example, configuration and function to the error current output circuit C1.

As illustrated in FIG. 3, the error current output circuit C1 includes a current comparator circuit COMP, a first amplifier circuit E1, and a second amplifier circuit E2.

The current comparator circuit COMP compares the monitor current Im1 obtained by monitoring the first output current IP1 and the reference current Iref. The current comparator circuit COMP outputs a first comparison result current I6 obtained by subtracting the monitor current Im1 from the reference current Iref and a second comparison result current I7 obtained by subtracting the reference current Iref from the monitor current Im1.

As illustrated in FIG. 3, the current comparator circuit COMP includes, for example, a first current source 101, a first MOS transistor (nMOS transistor) M1 of a first conductivity type, a second MOS transistor (pMOS transistor) M2 of the second conductivity type, a third MOS transistor (nMOS transistor) M3 of the first conductivity type, a fourth MOS transistor (pMOS transistor) M4 of the second conductivity type, a fifth MOS transistor (nMOS transistor) M5 of the first conductivity type, a sixth MOS transistor (nMOS transistor) M6 of the first conductivity type, a seventh MOS transistor (pMOS transistor) M7 of the second conductivity type, an eighth MOS transistor (pMOS transistor) M8 of the second conductivity type, a ninth MOS transistor (nMOS transistor) M9 of the first conductivity type, a tenth MOS transistor (pMOS transistor) M10 of the second conductivity type, and an eleventh MOS transistor (nMOS transistor) M11 of the first conductivity type.

The first current source 101 has one end connected to the first potential line L1 and outputs a current Ia.

The first MOS transistor M1 is diode-connected between the other end of the first current source 101 and the second potential line L2. The current Ia passes through the first MOS transistor M1.

The second MOS transistor M2 is diode-connected and has one end (source) connected to the first potential line L1 and the other end (drain) connected to a monitor current input terminal IIN-fed with the monitor current Im1. The second MOS transistor M2 is fed with a current I2.

The third MOS transistor M3 is connected between the other end (drain) of the second MOS transistor M2 and the second potential line L2 and has a gate connected to the gate of the first MOS transistor M1.

The third MOS transistor M3 is fed with a current I1. The current I1 is obtained by current-mirroring the current Ia.

Assuming that the first MOS transistor M1 and the third MOS transistor M3 are identical in size, the current I1 is expressed by equation (1) below.

I1=Ia (1)

The current I2 is the sum of the current I1 and the monitor current Im1 and thus is expressed by equation (2) according to equation (1).

I2=Ia+Im1 (2)

The fourth MOS transistor M4 has one end (source) connected to the first potential line L1, the other end (drain) connected to a reference current input terminal IIN+ fed with the reference current Iref, and a gate connected to the gate of the second MOS transistor M2.

Assuming that the fourth MOS transistor M4 and the second MOS transistor M2 are identical in size, the fourth MOS transistor M4 is fed with the same current I2, that is, a current obtained by current-mirroring the current I2 passing through the second MOS transistor M2.

The fifth MOS transistor M5 is connected between the other end (drain) of the fourth MOS transistor M4 and the second potential line L2 and has a gate connected to the gate of the first MOS transistor M1.

The sixth MOS transistor M6 is connected between the other end (drain) of the fourth MOS transistor M4 and the second potential line L2 and has a gate connected to the gate of the first MOS transistor M1.

Assuming that the first MOS transistor M1 and the fifth and sixth MOS transistors M5 and M6 are identical in size, the fifth and sixth MOS transistors M5 and M6 are fed with the same current Ia, that is, a current obtained by current-mirroring the current Ia passing through the first MOS transistor M1.

Thus, a current I3 passing through the fifth and sixth MOS transistors M5 and M6 is expressed by equation (3) below.

I3=Ia×2 (3)

A current I4 is the sum of the current I3 and the reference current Iref and thus is expressed by equation (4) below according to equation (3).

I4=Ia×2+Iref (4)

The seventh MOS transistor M7 is diode-connected and has one end (source) connected to the first potential line L1 and the other end (drain) connected to the reference current input terminal ITN+.

The sum of a current I5 passing through the seventh MOS transistor M7 and the current I2 passing through the fourth MOS transistor M4 is the current I4. Thus, the current I5 is expressed by equation (5) below according to equations (2) and (4).

$$\begin{matrix}I 5 = I 4 - I 2 \\ = Ia \times 2 + Iref - ( Ia + Im 1 ) \\ = Ia + Iref - Im 1\end{matrix} \qquad ( 5 )$$

The eighth MOS transistor M8 has one end (source) connected to the first potential line L1, a gate connected to the gate of the seventh MOS transistor M7, and the other end (drain) connected to a first comparison result terminal TCOMP1 for outputting the first comparison result current I6.

Assuming that the eighth MOS transistor M8 and the seventh MOS transistor M7 are identical in size, the eighth MOS transistor M8 is fed with the same current I5, that is, a current obtained by current-mirroring the current I5 passing through the seventh MOS transistor M7.

The ninth MOS transistor M9 is connected between the other end (drain) of the eighth MOS transistor M8 and the second potential line L2 and has a gate connected to the gate of the first MOS transistor M1.

Assuming that the ninth MOS transistor M9 and the first MOS transistor M1 are identical in size, the ninth MOS transistor M9 is fed with the same current Ia, that is, a current obtained by current-mirroring the current Ia passing through the first MOS transistor M1. In other words, the ninth MOS transistor M9 is fed with the current I1.

Thus, the first comparison result current I6 is obtained by subtracting the current I1 passing through the ninth MOS transistor M9 from the current I5 passing through the eighth MOS transistor M8.

Hence, the first comparison result current I6 is expressed by equation (6) below according to equation (5).

$$\begin{matrix}I 6 = I 5 - I 1 \\ = Ia + ( Iref - Im 1 ) - Ia \\ = Iref - Im 1\end{matrix} \qquad ( 6 )$$

The tenth MOS transistor M10 has one end connected to the first potential line L1, a gate connected to the gate of the seventh MOS transistor M7, and the other end connected to a second comparison result terminal TCOMP2 for outputting the second comparison result current I7.

Assuming that the tenth MOS transistor M10 and the seventh MOS transistor M7 are identical in size, the tenth MOS transistor M10 is fed with the same current I5, that is, a current obtained by current-mirroring the current I5 passing through the seventh MOS transistor M7.

The eleventh MOS transistor M11 is connected between the other end (drain) of the tenth MOS transistor M10 and the second potential line L2 and has a gate connected to the gate of the first MOS transistor M1.

Assuming that the eleventh MOS transistor M11 and the first MOS transistor M1 are identical in size, the eleventh MOS transistor M11 is fed with the same current Ia, that is, a current obtained by current-mirroring the current Ia passing through the first MOS transistor M1. In other words, the eleventh MOS transistor M11 is fed with the current I1.

Thus, the second comparison result current I7 is obtained by subtracting the current I5 passing through the tenth MOS transistor M10 from the current I1 passing through the eleventh MOS transistor M11.

Hence, the second comparison result current I7 is expressed by equation (7) below according to equation (5).

$$\begin{matrix}I 7 = I 1 - I 5 \\ = Ia - ( Ia + ( Iref - Im 1 ) ) \\ = Im 1 - Iref\end{matrix} \qquad ( 7 )$$

The first amplifier circuit E1 amplifies the first comparison result current I6 to output a first amplified current Ix1 of a first polarity (positive).

As illustrated in FIG. 3, the first amplifier circuit E1 includes, for example, a twelfth MOS transistor (nMOS transistor) M12 of the first conductivity type, a thirteenth MOS transistor (pMOS transistor) M13 of the second conductivity type, a fourteenth MOS transistor (nMOS transistor) M14 of the first conductivity type, and a fifteenth MOS transistor M15 of the second conductivity type.

The twelfth MOS transistor M12 is diode-connected and has one end (drain) connected to the other end (drain) of the eighth MOS transistor M8, that is, the first comparison result terminal TCOMP1 and the other end (source) connected to the second potential line L2.

The twelfth MOS transistor M12 is fed with the first comparison result current I6. In the case where the reference current Iref is smaller than the monitor current Im1, the first comparison result current I6 does not pass through the twelfth MOS transistor M12 (zero).

The thirteenth MOS transistor M13 is diode-connected and has one end (source) connected to the first potential line L1.

The fourteenth MOS transistor M14 is connected between the other end (drain) of the thirteenth MOS transistor M13 and the second potential line L2 and has a gate connected to the gate of the twelfth MOS transistor M12.

The fourteenth MOS transistor 14 is fed with a current obtained by current-mirroring the first comparison result current I6 passing through the twelfth MOS transistor M12.

The fifteenth MOS transistor M15 has one end (source) connected to the first potential line L1, the other end (drain) connected to the error current terminal IOUT, and a gate connected to the gate of the thirteenth MOS transistor M13.

The fifteenth MOS transistor M15 is fed with the first amplified current Ix1 that is obtained by current-mirroring a current passing through the thirteenth MOS transistor M13 (that is, a current obtained by current-mirroring the first comparison result current I6).

The fifteenth MOS transistor M15 is larger in size than, for example, the second, fourth, seventh, eighth, tenth, thirteenth, sixteenth, and seventeenth MOS transistor M2, M4, M7, M8, M10, M13, M16, and M17, which determines a mirror ratio larger than 1, so that the first amplified current Ix1 is an amplified current of the first comparison result current I6.

Moreover, the second amplifier circuit E2 amplifies the second comparison result current I7 to output a second amplified current Ix2 of a second polarity (negative) that is opposite to the first polarity (positive).

As illustrated in FIG. 3, the second amplifier circuit E2 includes, for example, a sixteenth MOS transistor (pMOS transistor) M16 of the second conductivity type, a seventeenth MOS transistor (pMOS transistor) M17 of the second conductivity type, an eighteenth MOS transistor (nMOS transistor) M18 of the first conductivity type, and a nineteenth MOS transistor (nMOS transistor) M19 of the first conductivity type.

The sixteenth MOS transistor M16 is diode-connected and has one end (source) connected to the first potential line L1 and the other end (drain) connected to the other end (drain) of the tenth MOS transistor M10, that is, the second comparison result terminal TCOMP2.

The sixteenth MOS transistor M16 is fed with the second comparison result current I7. In the case where the reference current Iref is larger than the monitor current Im1, the second comparison result current I7 does not pass through the sixteenth MOS transistor M16 (zero).

The seventeenth MOS transistor M17 has one end (source) connected to the first potential line L1 and a gate connected to the gate of the sixteenth MOS transistor M16.

The seventeenth MOS transistor 17 is fed with a current obtained by current-mirroring the second comparison result current 17 passing through the sixteenth MOS transistor M16.

The eighteenth MOS transistor M18 is diode-connected between the other end (drain) of the seventeenth MOS transistor M17 and the second potential line L2.

The nineteenth MOS transistor M19 has one end (drain) connected to the error current terminal IOUT, the other end (source) connected to the second potential line L2, and a gate connected to the gate of the eighteenth MOS transistor M18.

The nineteenth MOS transistor M19 is fed with the second amplified current Ix2 obtained by current-mirroring a current passing through the eighteenth MOS transistor M18 (that is, a current obtained by current-mirroring the second comparison result current I7).

The nineteenth MOS transistor is larger in size than, for example, the first, third, fifth, sixth, ninth, eleventh, twelfth, fourteenth, eighteenth, and nineteenth MOS transistors, which determines a mirror ratio larger than 1, so that the second amplified current Ix2 is an amplified current of the second comparison result current I7.

As described above, in the case where the reference current Iref is larger than the monitor current Im1, the error current output circuit C1 outputs the first amplified current Ix1 as the error current Ie1 from the error current terminal IOUT.

As described above, in the case where the reference current Iref is larger than the monitor current Im1, the second comparison result current I7 is not applied, precluding the passage of the second amplified current Ix2.

In the case where the reference current Iref is smaller than the monitor current Im1, the error current output circuit C1 outputs the second amplified current Ix2 as the error current Ie1 from the error current terminal IOUT.

As described above, in the case where the reference current Iref is smaller than the monitor current Im1, the first comparison result current I6 is not applied, precluding the passage of the first amplified current Ix1.

The error current output circuit C1 may be operated all the time after turn-on or may be operated in a predetermined period after turn-on.

The semiconductor memory 1000 configured thus compares the reference current Iref and the monitor currents Im1 to Imn and supplies or draws the error currents Ie1 to Ien to or from the current of the constant current output circuit, so that the error currents Ie1 to Ien are eliminated.

This method can eliminate the need for conventional trimming switches and control system circuits and further eliminate the need for a test time for trimming.

Conventionally, adjustments can be only made with a minimum step width by a trimming circuit, whereas the semiconductor integrated circuit 100 according to the first embodiment can automatically adjust a current in a stepless manner, eliminating the need for storing trimming data unlike in a conventional circuit.

For reference, the following will discuss an example of simulation results on the characteristics of the semiconductor integrated circuit 100 having the foregoing configuration and functions.

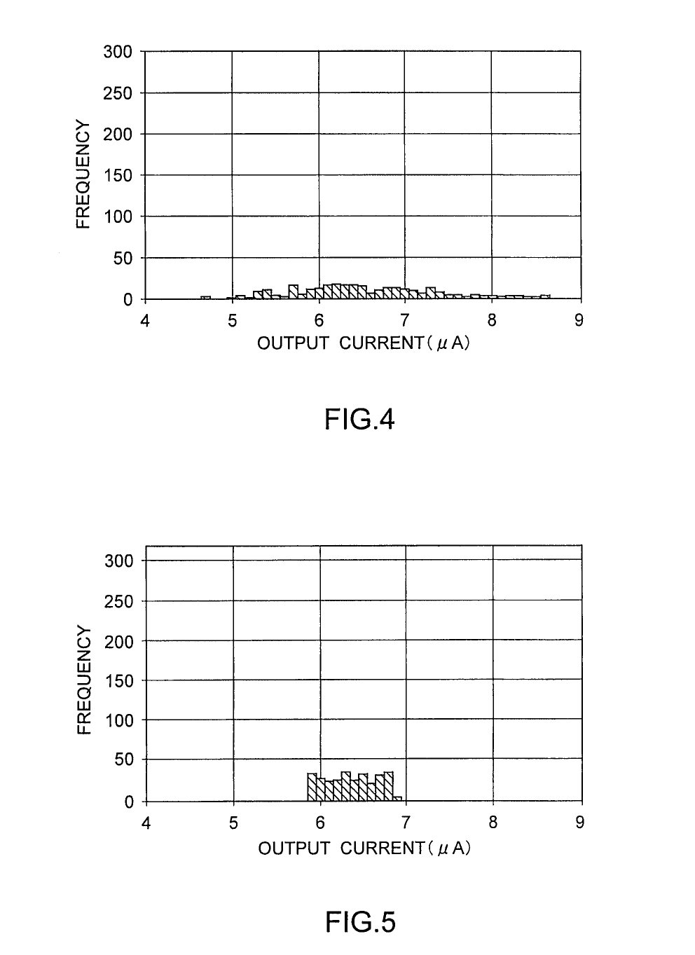

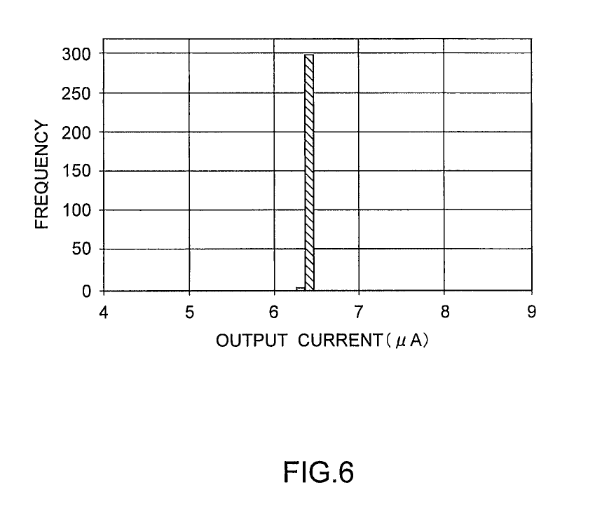

FIG. 4 shows an output current distribution of the constant current output circuit without the application of the first embodiment. FIG. 5 shows a current distribution when a constant current from a constant current output circuit is trimmed by a conventional trimming circuit. FIG. 6 shows an output current distribution of the semiconductor integrated circuit 100 according to the first embodiment.

As shown in FIG. 4, without the application of the first embodiment, an output current of the constant current output circuit is widely distributed.

Contrary to the output current distribution, as shown in FIG. 5, a conventional trimming circuit trims a constant current from the constant current output circuit, so that the output current is narrowly distributed.

However, as described above, the semiconductor integrated circuit 100 according to the first embodiment can steplessly adjust a current. Hence, as shown in FIG. 6, the output current distribution of the semiconductor integrated circuit 100 according to the first embodiment is narrower than that obtained by trimming an output current with a trimming circuit in FIG. 5.

As described above, the semiconductor integrated circuit 100 according to the first embodiment can output a constant current with higher precision.

In the first embodiment, the first polarity is positive, the second polarity is negative, the first potential line L1 is connected to a power supply VDD, the second potential line L2 is connected to ground VSS, the MOS transistor of the first conductivity type is a nMOS transistor, and the MOS transistor of the second conductivity type is a pMOS transistor.

In the first embodiment, however, the same effect can be obtained even with reversed circuit polarities. In other words, the first polarity may be negative, the second polarity may be positive, the first potential line L1 may be connected to the ground, the second potential line L2 may be connected to the power supply, the MOS transistor of the first conductivity type may be a pMOS transistor, and the MOS transistor of the second conductivity type may be a nMOS transistor.

### Second Embodiment

In the first embodiment, the error current output circuit and the constant current output circuit are provided in a one-to-one relationship.

In a second embodiment, a signal error current output circuit is provided for a plurality of constant current output circuits with a selecting circuit. Thus, a smaller circuit area can be obtained as compared with the configuration of the first embodiment.

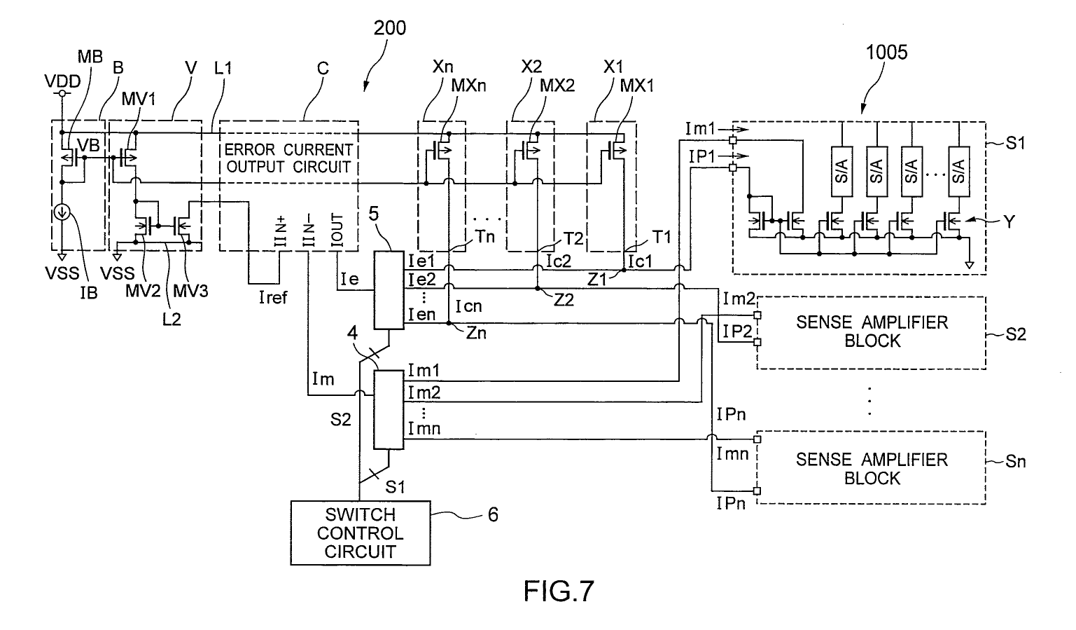

FIG. 7 illustrates an example of the configuration of a semiconductor integrated circuit 200 according to the second embodiment. In FIG. 7, the same reference numerals as in FIG. 2 indicate the same configurations as in the first embodiment.

As illustrated in FIG. 7, as in the first embodiment, the semiconductor integrated circuit 200 supplies output currents IP1 to IPn to sense amplifier blocks S1 to Sn through first to n-th output terminals Z1 to Zn.

As has been discussed, the sense amplifier blocks S1 to Sn respectively output monitor currents Im1 to Imn obtained by current-mirroring the output currents IP1 to IPn by means of current mirror circuits Y. Moreover, the semiconductor integrated circuit 200 compares the monitor currents Im1 to Imn and a reference current Iref and adjust the output currents IP1 to IPn to a predetermined value based on the comparison result.

As illustrated in FIG. 7, the semiconductor integrated circuit 200 includes, for example, first, second, . . . and n-th constant current output circuits X1, X2, . . . and Xn, an error current output circuit C, a bias voltage generating circuit B, a reference current generating circuit V, a current selecting circuit 5, and a switch control circuit 6.

Specifically, unlike in the first embodiment, the semiconductor integrated circuit 200 includes the unified error current output circuit and further includes a monitor selecting circuit 4, the current selecting circuit 5, and the switch control circuit 6.

The current selecting circuit 5 outputs an error current Ie supplied from an error current terminal IOUT, to one of the first output terminal Z1 to the n-th output terminal Zn.

In other words, the error current Ie is supplied as one of error currents Ie1 to Ien selected by the current comparator circuit 5, to one of the sense amplifier blocks S1 to Sn.

The monitor selecting circuit 4 selects one of the first monitor current Im1 obtained by monitoring the output current IP1 outputted from the first output terminal Z1 to the n-th monitor current Imn obtained by monitoring the output current IPn outputted from the n-th output terminal Zn, and then the monitor selecting circuit 4 outputs the selected monitor current.

In other words, one of the first monitor current Im1 to the n-th monitor current Imn is selected by the monitor selecting circuit 4 and the selected current is supplied as a monitor current Im to the error current output circuit C.

The error current output circuit C outputs the error current Ie from the error current terminal IOUT. The error current output circuit C is identical in configuration to the error current output circuit C1 of the first embodiment.

As in the first embodiment, in the case where the reference current Iref is larger than the monitor current Im, the error current output circuit C outputs a first amplified current Ix1 as the error current Ie from the error current terminal IOUT.

Furthermore, as in the first embodiment, in the case where the reference current Iref is smaller than the monitor current, the error current output circuit C outputs a second amplified current Ix2 as the error current Ie from the error current terminal IOUT.

The switch control circuit 6 controls the current selecting circuit 5 and the monitor selecting circuit 4 by means of control signals S1 and S2.

For example, in the case where the switch control circuit 6 controls the current selecting circuit 5 to output the error current Ie1 to the first output terminal Z1, the switch control circuit 6 controls the monitor selecting circuit 4 to select the first monitor current Im1 and output the current to a current comparator circuit COMP.

Thus, the output current IP1 outputted from the first output terminal Z1 is adjusted to the predetermined value by the operations of the error current output circuit C.

In the case where the switch control circuit 6 controls the current selecting circuit 5 to output the error current Ie2 to the second output terminal Z2, the switch control circuit 6 controls the monitor selecting circuit 4 to select the second monitor current Im2 and output the current to the current comparator circuit COMP.

Thus, the output current IP2 outputted from the second output terminal Z2 is adjusted to the predetermined value by the operations of the error current output circuit C.

Likewise, in the case where the switch control circuit 6 controls the current selecting circuit 5 to output the error current Ien to the n-the output terminal Zn, the switch control circuit 6 controls the monitor selecting circuit 4 to select the n-th monitor current Imn and output the current to the current comparator circuit COMP.

Thus, the output current IPn outputted from the n-th output terminal Zn is adjusted to the predetermined value by the operations of the error current output circuit C.

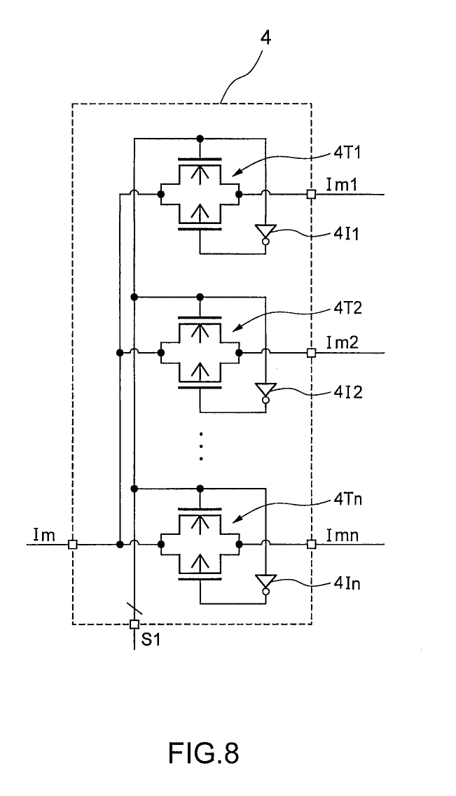

FIG. 8 is a circuit diagram illustrating an example of the configuration of the monitor selecting circuit 4 illustrated in FIG. 7. The current selecting circuit 5 in FIG. 7 has a similar configuration.

As illustrated in FIG. 8, the monitor selecting circuit 4 includes n transfer gates 4T1 to tTn and n inverters 4I1 to 4In.

One of the transfer gates 4T1 to tTn is turned on in response to the control signal S1.

For example, when the transfer gate 4T1 is turned on in response to the control signal S1, the first monitor current Im1 is selected and supplied as the monitor current Im to the current comparator circuit COMP.

Likewise, when the transfer gate 4Tn is turned on in response to the control signal S1, the n-th monitor current Imn is selected and supplied as the monitor current Im to the current comparator circuit COMP.

Other configurations of the semiconductor integrated circuit 200 are identical to those of the first embodiment.

In other words, the semiconductor integrated circuit 200 according to the second embodiment can output a constant current with higher precision as in the first embodiment.

As described above, in the second embodiment, the error current output circuit C is shared by the first to n-th constant current output circuits X1 to Xn and the sense amplifier blocks S1 to Sn. Hence, the circuit area of the semiconductor integrated circuit can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a first constant current output circuit that outputs a first constant current from a first constant current terminal to a first output terminal; and
an error current output circuit that outputs an error current from an error current terminal to the first output terminal,
the error current output circuit including:
a current comparator circuit that compares a monitor current obtained by monitoring an output current from the first output terminal and a reference current, outputs a first comparison result current obtained by subtracting the monitor current from the reference current, and outputs a second comparison result current obtained by subtracting the reference current from the monitor current;
a first amplifier circuit that amplifies the first comparison result current to output a first amplified current of a first polarity; and
a second amplifier circuit that amplifies the second comparison result current to output a second amplified current of a second polarity opposite to the first polarity,
wherein in the case where the reference current is larger than the monitor current, the first amplified current is outputted as the error current from the error current terminal, and
in the case where the reference current is smaller than the monitor current, the second amplified current is outputted as the error current from the error current terminal.

2. The semiconductor integrated circuit according to claim 1, wherein the first constant current output circuit includes a constant current MOS transistor having a first end connected to a first potential line, a gate fed with a bias voltage, and a second end from which the first constant current is outputted.

3. The semiconductor integrated circuit according to claim 1, wherein the current comparator circuit includes:
a first current source that has a first end connected to a first potential line and outputs a current;
a first MOS transistor of a first conductivity type, the first MOS transistor being diode-connected between a second end of the first current source and a second potential line;
a second MOS transistor of a second conductivity type, the second MOS transistor being diode-connected and having a first end connected to the first potential line and a second end connected to a monitor current input terminal fed with the monitor current;
a third MOS transistor of the first conductivity type, the third MOS transistor being connected between the second end of the second MOS transistor and the second potential line and having a gate connected to a gate of the first MOS transistor;
a fourth MOS transistor of the second conductivity type, the fourth MOS transistor having a first end connected to the first potential line, a second end connected to a reference current input terminal fed with the reference current, and a gate connected to a gate of the second MOS transistor;
a fifth MOS transistor of the first conductivity type, the fifth MOS transistor being connected between the second end of the fourth MOS transistor and the second potential line and having a gate connected to the gate of the first MOS transistor;
a sixth MOS transistor of the first conductivity type, the sixth MOS transistor being connected between the second end of the fourth MOS transistor and the second potential line and having a gate connected to the gate of the first MOS transistor;
a seventh MOS transistor of the second conductivity type, the seventh MOS transistor being diode-connected and having first end connected to the first potential line and a second end connected to the reference current input terminal;
an eighth MOS transistor of the second conductivity type, the eighth MOS transistor having a first end connected to the first potential line, a gate connected to a gate of the seventh MOS transistor, and a second end connected to a first comparison result terminal for outputting the first comparison result current;
a ninth MOS transistor of the first conductivity type, the ninth MOS transistor being connected between the second end of the eighth MOS transistor and the second potential line and having a gate connected to the gate of the first MOS transistor;
a tenth MOS transistor of the second conductivity type, the tenth MOS transistor having a first end connected to the first potential line, a gate connected to the gate of the seventh MOS transistor, and a second end connected to a second comparison result terminal for outputting the second comparison result current; and
an eleventh MOS transistor of the first conductivity type, the eleventh MOS transistor being connected between the second end of the tenth MOS transistor and the second potential line and having a gate connected to the gate of the first MOS transistor.

4. The semiconductor integrated circuit according to claim 3, wherein the first amplifier circuit includes:
a twelfth MOS transistor of the first conductivity type, the twelfth MOS transistor being diode-connected and having a first end connected to the second end of the eighth MOS transistor and a second end connected to the second potential line;
a thirteenth MOS transistor of the second conductivity type, the thirteenth MOS transistor being diode-connected and having a first end connected to the first potential line;
a fourteenth MOS transistor of the first conductivity type, the fourteenth MOS transistor being connected between a second end of the thirteenth MOS transistor and the second potential line and having a gate connected to a gate of the twelfth MOS transistor; and
a fifteenth MOS transistor of the second conductivity type, the fifteenth MOS transistor having a first end connected to the first potential line, a second end connected to the error current terminal, and a gate connected to a gate of the thirteenth MOS transistor, and
the second amplifier circuit includes:
a sixteenth MOS transistor of the second conductivity type, the sixteenth MOS transistor being diode-connected and having a first end connected to the first potential line and a second end connected to the second end of the tenth MOS transistor;
a seventeenth MOS transistor of the second conductivity type, the seventeenth MOS transistor having a first end connected to the first potential line and a gate connected to a gate of the sixteenth MOS transistor;
an eighteenth MOS transistor of the first conductivity type, the eighteenth MOS transistor being diode-connected between a second end of the seventeenth MOS transistor and the second potential line; and
a nineteenth MOS transistor of the first conductivity type, the nineteenth MOS transistor having a first end connected to the error current terminal, a second end connected to the second potential line, and a gate connected to a gate of the eighteenth MOS transistor.

5. The semiconductor integrated circuit according to claim 1, further comprising a bias voltage generating circuit that generates the bias voltage,
the bias voltage generating circuit including:
a first bias MOS transistor of a second conductivity type, the first bias MOS transistor having a first end connected to a first potential line and a second end from which the bias voltage is outputted; and
a bias current source connected between the second end of the first bias MOS transistor and a second potential line to output a current.

6. The semiconductor integrated circuit according to claim 5, further comprising a reference current generating circuit that generates the reference current,
the reference current generating circuit including:
a first reference MOS transistor of the second conductivity type, the first reference MOS transistor having a first end connected to the first potential line and a gate connected to a gate of the first bias MOS transistor;
a second reference MOS transistor of the second conductivity type, the second reference MOS transistor being diode-connected between a second end of the first reference MOS transistor and the second potential line; and
a third reference MOS transistor having a first end from which the reference current is outputted, a second end connected to the second potential line, and a gate connected to a gate of the second reference MOS transistor.

7. A semiconductor integrated circuit comprising:
a first constant current output circuit that outputs a first constant current from a first constant current terminal to a first output terminal;
a second constant current output circuit that outputs a second constant current from a second constant current terminal to a second output terminal;
an error current output circuit that outputs an error current from an error current terminal;
a current selecting circuit that outputs the error current supplied from the error current terminal, to one of the first output terminal and the second output terminal;
a monitor selecting circuit that selects one of a first monitor current and a second monitor current and outputs the monitor current, the first monitor current being obtained by monitoring an output current from the first output terminal, the second monitor current being obtained by monitoring an output current from the second output terminal; and
a switch control circuit that controls the current selecting circuit and the monitor selecting circuit,
the error current output circuit including:
a current comparator circuit that compares the monitor current outputted from the monitor selecting circuit and a reference current, outputs a first comparison result current obtained by subtracting the monitor current from the reference current, and outputs a second comparison result current obtained by subtracting the reference current from the monitor current;
a first amplifier circuit that amplifies the first comparison result current to output a first amplified current of a first polarity; and
a second amplifier circuit that amplifies the second comparison result current to output a second amplified current of a second polarity opposite to the first polarity,
wherein in the case where the reference current is larger than the monitor current, the first amplified current is outputted as the error current from the error current terminal,
in the case where the reference current is smaller than the monitor current, the second amplified current is outputted as the error current from the error current terminal,
in the case where the switch control circuit controls the current selecting circuit to output the error current to the first output terminal, the switch control circuit controls the monitor selecting circuit to select the first monitor current and output the current to the current comparator circuit, and
in the case where the switch control circuit controls the current selecting circuit to output the error current to the second output terminal, the switch control circuit controls the monitor selecting circuit to select the second monitor current and output the current to the current comparator circuit.

8. The semiconductor integrated circuit according to claim 7, wherein the second constant current output circuit is identical in configuration to the first constant current output circuit.

9. The semiconductor integrated circuit according to claim 7, wherein the first constant current output circuit includes a constant current MOS transistor having a first end connected to a first potential line, a gate fed with a bias voltage, and a second end from which the first constant current is outputted.

10. The semiconductor integrated circuit according to claim 7, wherein the current comparator circuit includes:
a first current source that has a first end connected to a first potential line and outputs a current;
a first MOS transistor of a first conductivity type, the first MOS transistor being diode-connected between a second end of the first current source and a second potential line;
a second MOS transistor of a second conductivity type, the second MOS transistor being diode-connected and having a first end connected to the first potential line and a second end connected to a monitor current input terminal fed with the monitor current;
a third MOS transistor of the first conductivity type, the third MOS transistor being connected between the second end of the second MOS transistor and the second potential line and having a gate connected to a gate of the first MOS transistor;
a fourth MOS transistor of the second conductivity type, the fourth MOS transistor having a first end connected to the first potential line, a second end connected to a reference current input terminal fed with the reference current, and a gate connected to a gate of the second MOS transistor;
a fifth MOS transistor of the first conductivity type, the fifth MOS transistor being connected between the second end of the fourth MOS transistor and the second potential line and having a gate connected to the gate of the first MOS transistor;
a sixth MOS transistor of the first conductivity type, the sixth MOS transistor being connected between the second end of the fourth MOS transistor and the second potential line and having a gate connected to the gate of the first MOS transistor;
a seventh MOS transistor of the second conductivity type, the seventh MOS transistor being diode-connected and having first end connected to the first potential line and a second end connected to the reference current input terminal;
an eighth MOS transistor of the second conductivity type, the eighth MOS transistor having a first end connected to the first potential line, a gate connected to a gate of the seventh MOS transistor, and a second end connected to a first comparison result terminal for outputting the first comparison result current;
a ninth MOS transistor of the first conductivity type, the ninth MOS transistor being connected between the second end of the eighth MOS transistor and the second potential line and having a gate connected to the gate of the first MOS transistor;
a tenth MOS transistor of the second conductivity type, the tenth MOS transistor having a first end connected to the first potential line, a gate connected to the gate of the seventh MOS transistor, and a second end connected to a second comparison result terminal for outputting the second comparison result current; and
an eleventh MOS transistor of the first conductivity type, the eleventh MOS transistor being connected between the second end of the tenth MOS transistor and the second potential line and having a gate connected to the gate of the first MOS transistor.

11. The semiconductor integrated circuit according to claim 10, wherein the first amplifier circuit includes:
a twelfth MOS transistor of the first conductivity type, the twelfth MOS transistor being diode-connected and having a first end connected to the second end of the eighth MOS transistor and a second end connected to the second potential line;
a thirteenth MOS transistor of the second conductivity type, the thirteenth MOS transistor being diode-connected and having a first end connected to the first potential line;
a fourteenth MOS transistor of the first conductivity type, the fourteenth MOS transistor being connected between a second end of the thirteenth MOS transistor and the second potential line and having a gate connected to a gate of the twelfth MOS transistor; and
a fifteenth MOS transistor of the second conductivity type, the fifteenth MOS transistor having a first end connected to the first potential line, a second end connected to the error current terminal, and a gate connected to a gate of the thirteenth MOS transistor, and
the second amplifier circuit includes:
a sixteenth MOS transistor of the second conductivity type, the sixteenth MOS transistor being diode-connected and having a first end connected to the first potential line and a second end connected to the second end of the tenth MOS transistor;
a seventeenth MOS transistor of the second conductivity type, the seventeenth MOS transistor having a first end connected to the first potential line and a gate connected to a gate of the sixteenth MOS transistor;
an eighteenth MOS transistor of the first conductivity type, the eighteenth MOS transistor being diode-connected between a second end of the seventeenth MOS transistor and the second potential line; and
a nineteenth MOS transistor of the first conductivity type, the nineteenth MOS transistor having a first end connected to the error current terminal, a second end connected to the second potential line, and a gate connected to a gate of the eighteenth MOS transistor.

12. The semiconductor integrated circuit according to claim 7, further comprising a bias voltage generating circuit that generates the bias voltage,
the bias voltage generating circuit including:
a first bias MOS transistor of a second conductivity type, the first bias MOS transistor having a first end connected to a first potential line and a second end from which the bias voltage is outputted; and
a bias current source connected between the second end of the first bias MOS transistor and a second potential line to output a current.

13. The semiconductor integrated circuit according to claim 12, further comprising a reference current generating circuit that generates the reference current,
the reference current generating circuit including:
a first reference MOS transistor of the second conductivity type, the first reference MOS transistor having a first end connected to the first potential line and a gate connected to a gate of the first bias MOS transistor;
a second reference MOS transistor of the second conductivity type, the second reference MOS transistor being diode-connected between a second end of the first reference MOS transistor and the second potential line; and
a third reference MOS transistor having a first end from which the reference current is outputted, a second end connected to the second potential line, and a gate connected to a gate of the second reference MOS transistor.

14. A semiconductor memory comprising:
a memory cell array;
a sense amplifier connected to the memory cell array; and
a semiconductor integrated circuit that outputs an output current to the sense amplifier from a first output terminal,
wherein the semiconductor integrated circuit comprising:
a first constant current output circuit that outputs a first constant current from a first constant current terminal to the first output terminal; and
an error current output circuit that outputs an error current from an error current terminal to the first output terminal,
the error current output circuit including:
a current comparator circuit that compares a monitor current obtained by monitoring an output current from the first output terminal and a reference current, outputs a first comparison result current obtained by subtracting the monitor current from the reference current, and outputs a second comparison result current obtained by subtracting the reference current from the monitor current;
a first amplifier circuit that amplifies the first comparison result current to output a first amplified current of a first polarity; and
a second amplifier circuit that amplifies the second comparison result current to output a second amplified current of a second polarity opposite to the first polarity,
wherein in the case where the reference current is larger than the monitor current, the first amplified current is outputted as the error current from the error current terminal, and
in the case where the reference current is smaller than the monitor current, the second amplified current is outputted as the error current from the error current terminal.

15. The semiconductor memory according to claim 14, wherein the first constant current output circuit includes a constant current MOS transistor having a first end connected to a first potential line, a gate fed with a bias voltage, and a second end from which the first constant current is outputted.

16. The semiconductor memory according to claim 14, wherein the current comparator circuit includes:
a first current source that has a first end connected to a first potential line and outputs a current;
a first MOS transistor of a first conductivity type, the first MOS transistor being diode-connected between a second end of the first current source and a second potential line;
a second MOS transistor of a second conductivity type, the second MOS transistor being diode-connected and having a first end connected to the first potential line and a second end connected to a monitor current input terminal fed with the monitor current;
a third MOS transistor of the first conductivity type, the third MOS transistor being connected between the second end of the second MOS transistor and the second potential line and having a gate connected to a gate of the first MOS transistor;
a fourth MOS transistor of the second conductivity type, the fourth MOS transistor having a first end connected to the first potential line, a second end connected to a reference current input terminal fed with the reference current, and a gate connected to a gate of the second MOS transistor;
a fifth MOS transistor of the first conductivity type, the fifth MOS transistor being connected between the second end of the fourth MOS transistor and the second potential line and having a gate connected to the gate of the first MOS transistor;
a sixth MOS transistor of the first conductivity type, the sixth MOS transistor being connected between the second end of the fourth MOS transistor and the second potential line and having a gate connected to the gate of the first MOS transistor;
a seventh MOS transistor of the second conductivity type, the seventh MOS transistor being diode-connected and having first end connected to the first potential line and a second end connected to the reference current input terminal;
an eighth MOS transistor of the second conductivity type, the eighth MOS transistor having a first end connected to the first potential line, a gate connected to a gate of the seventh MOS transistor, and a second end connected to a first comparison result terminal for outputting the first comparison result current;
a ninth MOS transistor of the first conductivity type, the ninth MOS transistor being connected between the second end of the eighth MOS transistor and the second potential line and having a gate connected to the gate of the first MOS transistor;
a tenth MOS transistor of the second conductivity type, the tenth MOS transistor having a first end connected to the first potential line, a gate connected to the gate of the seventh MOS transistor, and a second end connected to a second comparison result terminal for outputting the second comparison result current; and
an eleventh MOS transistor of the first conductivity type, the eleventh MOS transistor being connected between the second end of the tenth MOS transistor and the second potential line and having a gate connected to the gate of the first MOS transistor.

17. The semiconductor memory according to claim 16, wherein the first amplifier circuit includes:
a twelfth MOS transistor of the first conductivity type, the twelfth MOS transistor being diode-connected and having a first end connected to the second end of the eighth MOS transistor and a second end connected to the second potential line;
a thirteenth MOS transistor of the second conductivity type, the thirteenth MOS transistor being diode-connected and having a first end connected to the first potential line;
a fourteenth MOS transistor of the first conductivity type, the fourteenth MOS transistor being connected between a second end of the thirteenth MOS transistor and the second potential line and having a gate connected to a gate of the twelfth MOS transistor; and
a fifteenth MOS transistor of the second conductivity type, the fifteenth MOS transistor having a first end connected to the first potential line, a second end connected to the error current terminal, and a gate connected to a gate of the thirteenth MOS transistor, and
the second amplifier circuit includes:
a sixteenth MOS transistor of the second conductivity type, the sixteenth MOS transistor being diode-connected and having a first end connected to the first potential line and a second end connected to the second end of the tenth MOS transistor;
a seventeenth MOS transistor of the second conductivity type, the seventeenth MOS transistor having a first end connected to the first potential line and a gate connected to a gate of the sixteenth MOS transistor;
an eighteenth MOS transistor of the first conductivity type, the eighteenth MOS transistor being diode-connected between a second end of the seventeenth MOS transistor and the second potential line; and
a nineteenth MOS transistor of the first conductivity type, the nineteenth MOS transistor having a first end connected to the error current terminal, a second end connected to the second potential line, and a gate connected to a gate of the eighteenth MOS transistor.

18. The semiconductor memory according to claim 14, further comprising a bias voltage generating circuit that generates the bias voltage,
the bias voltage generating circuit including:
a first bias MOS transistor of a second conductivity type, the first bias MOS transistor having a first end connected to a first potential line and a second end from which the bias voltage is outputted; and
a bias current source connected between the second end of the first bias MOS transistor and a second potential line to output a current.

19. The semiconductor memory according to claim 18, further comprising a reference current generating circuit that generates the reference current,
the reference current generating circuit including:
a first reference MOS transistor of the second conductivity type, the first reference MOS transistor having a first end connected to the first potential line and a gate connected to a gate of the first bias MOS transistor;
a second reference MOS transistor of the second conductivity type, the second reference MOS transistor being diode-connected between a second end of the first reference MOS transistor and the second potential line; and
a third reference MOS transistor having a first end from which the reference current is outputted, a second end connected to the second potential line, and a gate connected to a gate of the second reference MOS transistor.

20. The semiconductor memory according to claim 14, wherein the semiconductor memory is a flash memory.
